(19) United States
(12) Patent Application Publication
(10) Pub. No.: US 2008/0094894 A1
(43) Pub. Date: Apr. 24, 2008

(54) NONVOLATILE SEMICONDUCTOR MEMORY AND MEMORY SYSTEM

(75) Inventor: Toshiyuki HAYAKAWA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Mlnato-ku (JP)

(21) Appl. No.: 11/877,209

(22) Filed: Oct. 23, 2007

(30) Foreign Application Priority Data
Oct. 23, 2006 (JP) 2006-287821

(51) Int. Cl. G11C 16/04

(52) U.S. Cl. 365/185.03

(57) ABSTRACT

A nonvolatile semiconductor memory includes a plurality of memory cells each configured to store M bits of data, where M is an integer greater than 1. In addition, the memory includes a selection circuit configured to select a first or second mode according to an instruction from outside of the nonvolatile semiconductor memory, and a program circuit configured to program M bits of data into each memory cell in the first mode, and N bits of data into each memory cell in the second mode, where N is an integer less than M. A selection pin may receive a voltage as the instruction from outside the memory indicating the first or second mode. Further, each of the memory cells may be assigned N different page addresses in the first mode and M different page addresses in the second mode.

### CROSS REFERENCE TO A RELATED APPLICATION

This application is based upon and claims the benefit of priority from the prior Japanese Patent Application No. JP2006-287821 filed on Oct. 23, 2006, the entire contents of which are incorporated herein by reference.

### BACKGROUND OF THE INVENTION

1. Field of the Invention

The present invention relates to a nonvolatile semiconductor memory and a memory system including the nonvolatile semiconductor memory.

2. Discussion of the Background

Among NAND type flash memories, there are a binary NAND type flash memory (hereinafter a binary memory) which stores 1-bit data in one memory cell, and a multi-value NAND type flash memory (hereinafter a multi-value memory) which stores data 2-bits or more in one memory cell. Although the binary and multi-value memories do not differ in structures of the memory cells, their control circuits programming data into the memory cells are different from each other. The control circuit of the binary memory programs 1-bit data into each memory cell in a binary mode. The control circuit of the multi-value memory programs 2-bits or more of data into each memory cell in a multi-value mode. Therefore, the programming mode of NAND type flash memory cannot be switched between binary and multi-value modes.

For example, a conventional memory card such as an SD™ (Secure Digital) card is used as a storage medium of a host apparatus such as a personal computer. The memory card includes the NAND type flash memory and a controller accessing the NAND type flash memory. The conventional memory card cannot switch between binary and multi-value modes because the NAND type flash memory cannot switch its programming mode, even if the controller supports both the binary and multi-value modes.

A multi-value memory has a larger storage capacity compared to a binary memory of the same size because data 2-bits or more can be stored in one memory cell. Therefore, multi-value memory is more suitable than binary memory for uses requiring a large storage capacity.

On the other hand, binary memory can perform data writing and data erasing in a shorter time than multi-value memory. Therefore, binary memory is more suitable than multi-value memory for uses requiring high speed.

However, since conventional NAND type flash memory cannot switch between binary and multi-value modes as mentioned above, a user of the conventional NAND type flash memory cannot use the characteristics of binary and multi-value memories selectively according to an intended usage. Although binary NAND type flash memory and multi-value NAND type flash memory were mentioned in the above explanation, the same problem also exists in other nonvolatile semiconductor memories.

Japanese Patent Disclosure (Kokai) P2001-6374 discloses that a flash memory in a flash file system alternatively operates a memory cell in binary or multi-value mode according to a command.

### SUMMARY OF THE INVENTION

One object of the present invention is to provide a novel nonvolatile semiconductor memory comprising: a plurality of memory cells each configured to store M bits of data, M being an integer greater than 1; a selection circuit configured to select a first mode or a second mode according to an instruction from outside of the nonvolatile semiconductor memory; and a program circuit configured to program M bits of data into each of the memory cells when the selection circuit selects the first mode and program N bits of data into each of the memory cells when the selection circuit selects the second mode, N being an integer less than M.

### BRIEF DESCRIPTION OF THE DRAWINGS

FIG. 1 is an illustration schematically showing a structure of a nonvolatile semiconductor memory according to a first embodiment of the present invention.

FIG. 2 is an equivalent circuit diagram of a memory cell array.

FIG. 3 is a diagram showing a relationship between data and threshold states of a memory cell when a multi-value control circuit is selected.

FIG. 4 is a diagram showing a method of writing a lower page of data.

FIG. 5 is a diagram showing a method of writing a higher page of data.

FIG. 6 is a diagram showing a page address assignment of the memory cells when the multi-value control circuit is selected.

FIG. 7 is a diagram showing a relationship between data and threshold states of the memory cell when a binary control circuit is selected.

FIG. 8 is a diagram showing a method of programming in the data assignment shown in FIG. 7.

FIG. 9 is a diagram showing a page address assignment of the memory cells when the binary value control circuit is selected.

FIG. 10 is an illustration shows a package pin assignment of the NAND type flash memory according to the first embodiment.

FIG. 11 is a flow chart showing the operation of the NAND type flash memory according to the first embodiment.

FIG. 12 is a drawing schematically showing an outline composition of a memory card according to a second embodiment of the present invention.

FIG. 13 is a drawing showing an appearance of the memory card according to the second embodiment.

### DETAILED DESCRIPTION OF THE INVENTION

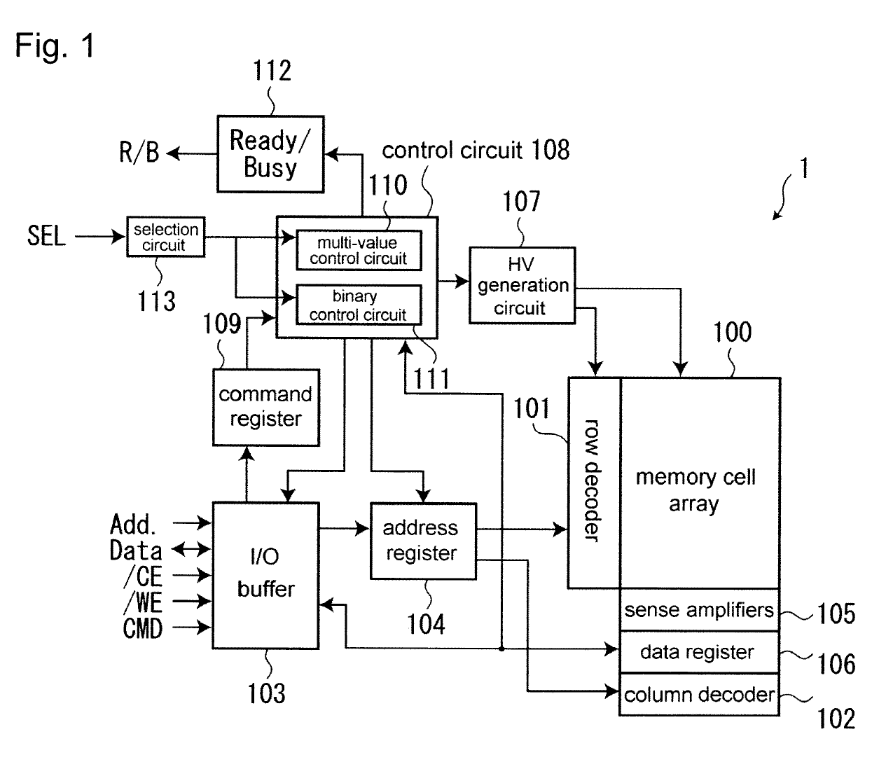

With reference to FIGS. 1 to 13, description will be given of embodiments of a nonvolatile semiconductor memory and a memory system. In this description, a NAND type flash memory is explained as an example of the nonvolatile semiconductor memory, and a memory card is explained as an example of the memory system. Like elements are denoted by like or similar reference numbers throughout the drawings.

### The First Embodiment

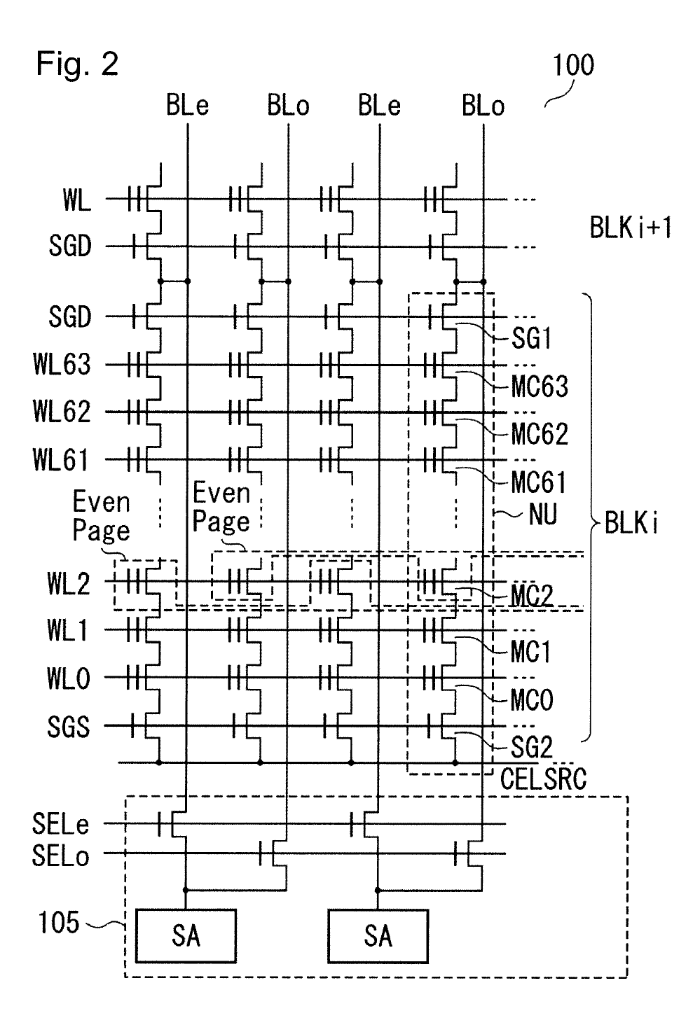

FIG. 1 shows a structure of a nonvolatile semiconductor memory according to a first embodiment of the present invention. FIG. 2 shows an equivalent circuit diagram of a memory cell array 100. The memory cell array 100 includes a plurality of memory cells. A row decoder 101 and a column decoder 102 select a word line and a bit line of the memory cell array 100, respectively. An address signal is input to an address register 104 through an I/O buffer 103, and the row decoder 101 and the column decoder 102 decode the address signal to select the memory cells. The bit lines of the memory cell array 100 are connected to sense amplifiers 105, and the sense amplifiers 105 are connected to the I/O buffer 103 through a data register 106.

A high voltage (HV) generation circuit 107 generates various kinds of high voltages used for data writing and data erasing. A control circuit 108 controls a sequence of data writing and data erasing including a verification operation. The control circuit 108 also controls the high voltage generation circuit 107 according to the mode of operation.

A command CMD, such as a write command or an erase command, is input to the command register 109 through the I/O buffer 103. The command latched by the command register 109 is decoded by the control circuit 108, and the operation such as data writing or data erasing is performed in accordance with the command.

The control circuit 108 includes a multi-value control circuit 110 and a binary control circuit 111. A selection circuit 113 activates only one of the multi-value control circuit 110 and the binary control circuit 111 by a select signal SEL input from a selection terminal SEL. The multi-value control circuit 110 controls a sequence of data writing so that data may be programmed in a multi-value mode. The multi-value control circuit 110 controls the row decoder 101 and the column decoder 102, and selects the memory cells so that data having 2-bits or more may be programmed into one memory cell. On the other hand, the binary control circuit 111 controls a sequence of data writing so that data having 1-bit may be programmed in a binary mode. The binary control circuit 111 controls the row decoder 101 and the column decoder 102, and selects the memory cells so that 1-bit data may be programmed into one memory cell. Thus, the control circuit 108 can change the programming mode between the binary and multi-value modes by selecting one of the multi-value control circuit 110 and the binary control circuit 111.

Various kinds of control signals including a chip enable signal /CE which activates or deactivates the NAND type flash memory are input to the I/O buffer 103. These control signals are also sent to the control circuit 108. The control circuit 108 outputs a busy signal to a terminal RIB through a Ready/Busy buffer 112, when the chip enable signal /CE is “H”.

FIG. 2 is a circuit layout diagram of an embodiment of a NAND cell unit (NAND string) NU, which is a base unit of the memory cell array 100 and includes two or more memory cells MC0-MC63 connected serially to each other, and two selection transistors SG1 and SG2 arranged on both sides of the memory cells MC0-MC63. One end of the NAND cell unit NU is connected to bit line BLo through the selection transistor SG1, and another end is connected to a common source line CELSRC through the selection transistor SG2.

One memory cell has n-type source/drain diffusion layers formed in a p-type well of a silicon substrate, and has a stacking gate structure of a floating gate as a charge-storage layer and a control gate. A threshold voltage of the memory cell is changed by changing an amount of electric charge accumulated in the floating gate, and multiple values of data may be programmed according to corresponding changes in the threshold voltage.

The control gate of each of the memory cells MC0-MC63 is connected to a different one of word lines WL0-WL63, and the gates of the selection transistors SG1 and SG2 are connected to selection gate lines SGD and SGS, respectively. A set of the NAND cell units sharing the word lines WL0-WL63 and the election gate lines SGD and SGS constitutes a block BLK as a unit of the data erasing. Usually, two or more blocks BLKi, BLKi+1 . . . are arranged in the direction of the bit lines as shown in FIG. 2.

The row decoder 101 controls the word lines WL0-WL63 and the selection gate lines SGD and SGS. The row decoder 101 has control gate (CG) decoder drivers of the same number as the word lines, a SGD driver controlling the drain side selection gate line SGD, and a SGS driver controlling the source side selection gate line SGS. These drivers are shared by two or more blocks of the memory cell array 100. One or more memory cells that share a row (e.g., one or more of the memory cells in a row sharing a word line) are considered to form a page, and therefore, a row address may constitute a page address. Moreover, a page address (row address) designating the word line in the NAND cell unit is input to the row decoder 101.

The NAND type flash memory uses Fowler-Nordheim (FN) tunnel current for the data writing and data erasing. In the NAND type flash memory, many memory cells can be programmed simultaneously since a current required for the threshold voltage shift of one memory cell is small. Therefore, the NAND type flash memory can read and write data in a unit of page. For example, the size of a page may be 2 k Bytes or 4 k Bytes. The number of sense units SA in the sense amplifiers 105, which constitute a page buffer, corresponds to the size of the page.

In the write operation, the column decoder 102 decodes the column address output from the address register 104, connects the selected sense units SA with the data register 106, and sets the write data for every column address into the sense amplifiers 105. The read operation is opposite to the write operation. Data simultaneously read out by the sense amplifier 105 is output to the data register 106 from the sense units SA selected according to the column address as decoded by the column decoder 102. In fact, the circuit for inputting and outputting data in a predetermined cycle is provided between the data register 106 and the sense amplifiers 105 although omitted in FIG. 1.

FIG. 2 shows an embodiment of a memory cell array 100 in which adjacent two sets of the bit lines (the odd number of the bit line BLo and the even number of the bit line BLe) share one sense unit SA. The even number of bit line BLe and the odd number of bit line BLo are alternatively connected to the sense unit SA by pulsing signals SELe and SELo at the time of writing or reading data. At this time, interference noise between the bit lines is prevented by the non-connected bit line functioning as a shielding wire.

FIG. 2 shows the case where the word line WL2 is selected. The memory cells positioning at the intersection of the word line WL2 and the even number of bit lines BLe constitute one page (even page) as a unit of simultaneous writing or reading. And, the memory cells positioning at the intersection of the word line WL2 and the odd number of bit lines BLo constitute another one page (odd page) as a unit of simultaneous writing or reading.

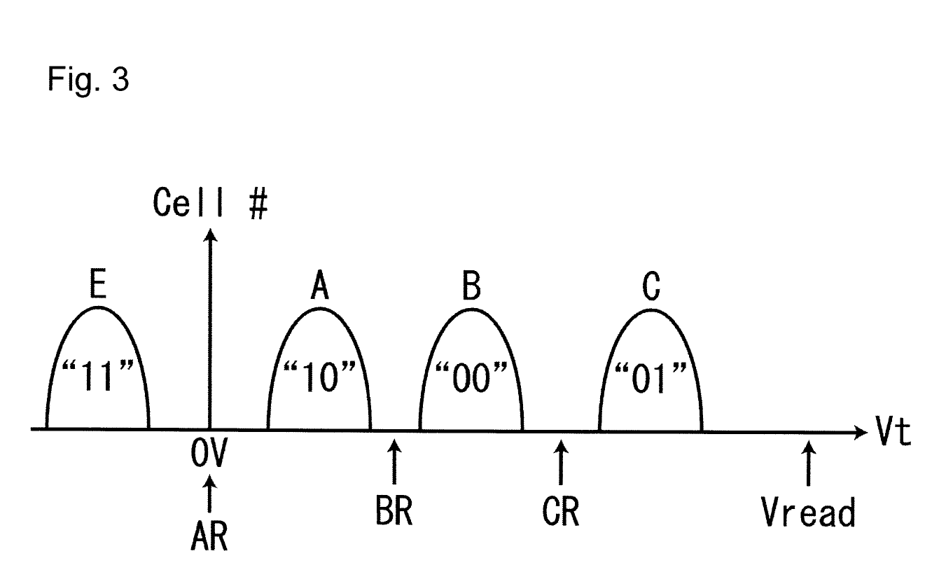

FIG. 3 shows a relationship between data and threshold states of a memory cell when the multi-value control circuit 110 is selected (4-value programming mode). In this embodiment, 2-bits of data programmed into one memory cell are assigned to two page addresses. That is, a lower bit of data is read when a lower page address is designated, and a higher bit of data is read when a higher page address is designated. Data “11” is assigned to an erase state E which is negative in the threshold voltage. Data “10”, “00”, and “01” are respectively assigned to write states A, B, and C.

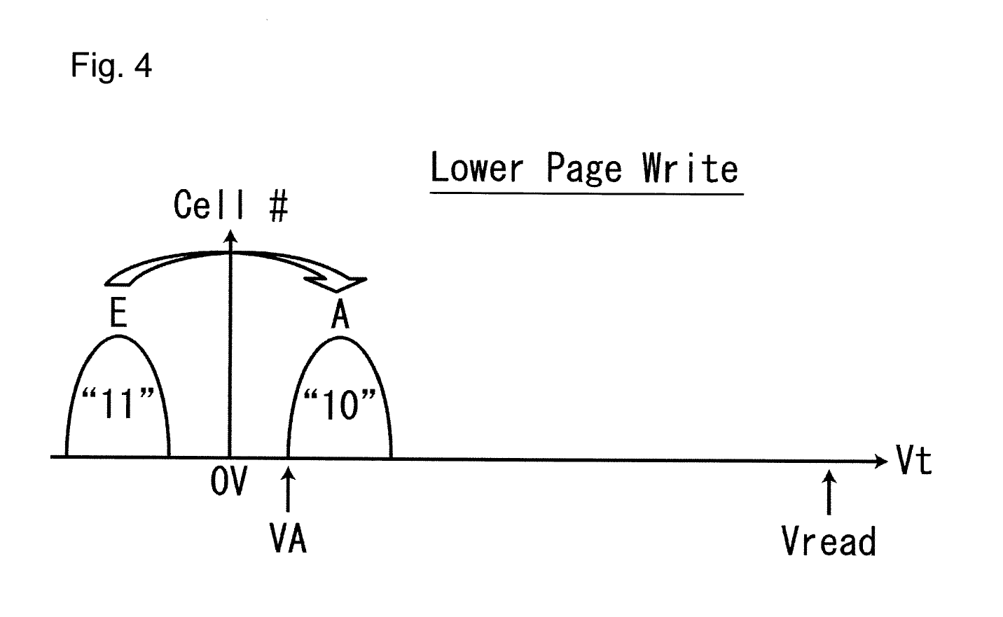

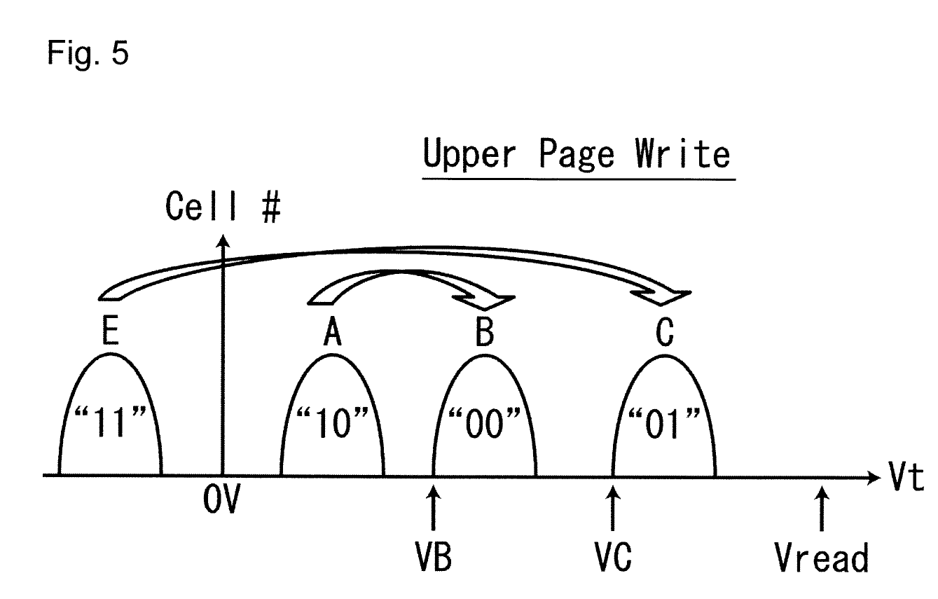

FIGS. 4 and 5 show methods of programming in the above data assignment. FIG. 4 shows a method of writing the lower bit of data. The threshold state A of data “10” is acquired by programming “0” into the memory cell in the erase state E of data “11.” When programming “1” in to the lower bit of a memory cell in state E (i.e., “11”), the memory cell to be programmed with data “1” in the lower bit of memory does not shift, but holds the data “11” state.

FIG. 5 shows a method of programming the higher bit of data. In the case of programming “0” into the higher bit of a memory cell in the state “11”, the threshold shifts from the state E to the state C (from data “11” to data “01”). In the case of programming “0” into the higher bit of a memory cell in the state “10”, the threshold shifts from the state A to the state B (from data “10” to data “00”). In the case of programming “1” into the higher bit of a memory cell in state E (i.e., “11”) or state A (i.e., “10”), the threshold of the memory cell remains unchanged (data “11” or data “10”).

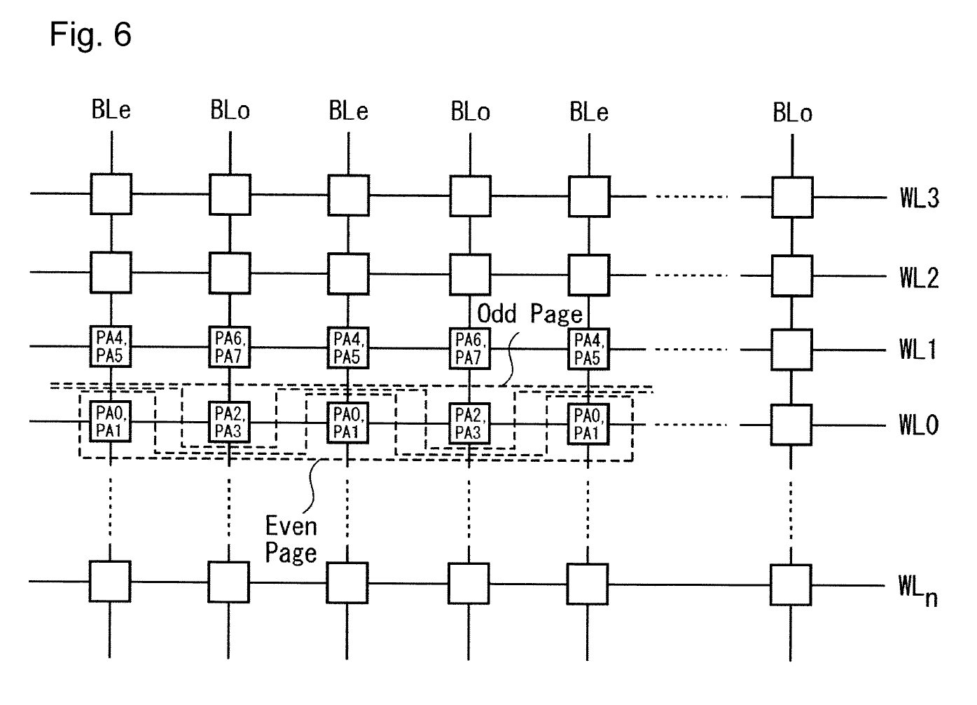

FIG. 6 shows a page address assignment of memory cells when the multi-value control circuit 110 is selected (4-value programming mode). A page address PA 0 is assigned to a lower page of the memory cell located at the intersection of the even number bit line BLe and a word line WL0. A page address PA 1 is assigned to a higher page of the memory cell located at the intersection of the even number bit line BLe and the word line WL0. A page address PA 2 is assigned to a lower page of the memory cell located at the intersection of the odd number bit line BLo and the word line WL0. A page address PA 3 is assigned to a higher page of the memory cell located at the intersection of the odd number bit line BLo and the word line WL0. Similarly, a page address PA 4 is assigned to a lower page of the memory cell located at the intersection of the even number bit line BLe and a word line WL1. A page address PA 5 is assigned to a higher page of the memory cell located at the intersection of the even number bit line BLe and the word line WL1. A page address PA 6 is assigned to a lower page of the memory cell located at the intersection of the odd number bit line BLo and the word line WL1. A page address PA 7 is assigned to a higher page of the memory cell located at the intersection of the odd number bit line BLo and the word line WL1. Thus, the multi-value control circuit 110 assigns two page addresses to one memory cell and makes one memory cell memorize 2-bits of data.

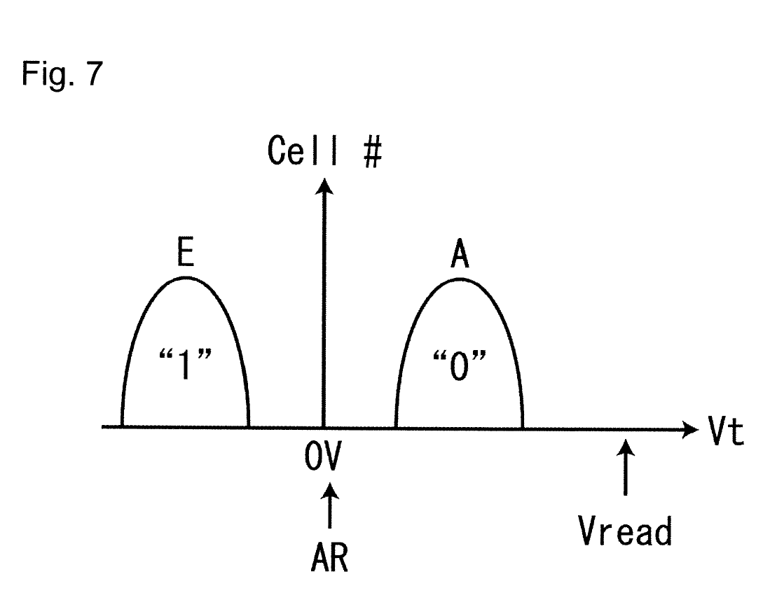

FIG. 7 shows a relationship between data and threshold states of a memory cell when the binary control circuit 111 is selected (binary programming mode). In this embodiment, 1-bit data programmed into one memory cell is assigned to one page address. Data “1” is assigned to the erase state E which is negative in the threshold. Data “0” is assigned to the write state A of a positive threshold.

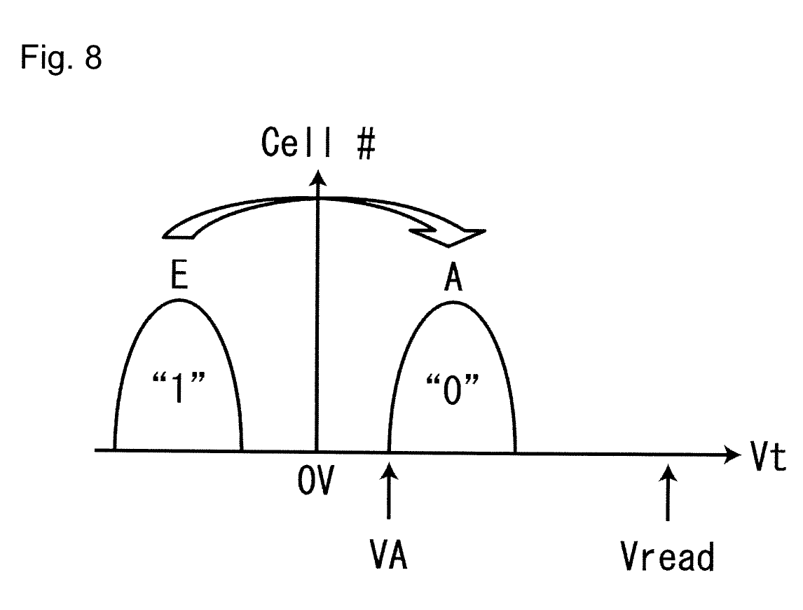

FIG. 8 shows a method of programming in the data assignment of FIG. 7. The threshold state A of data “0” is acquired by programming “0” into the memory cell in the erase state E of data “1”.

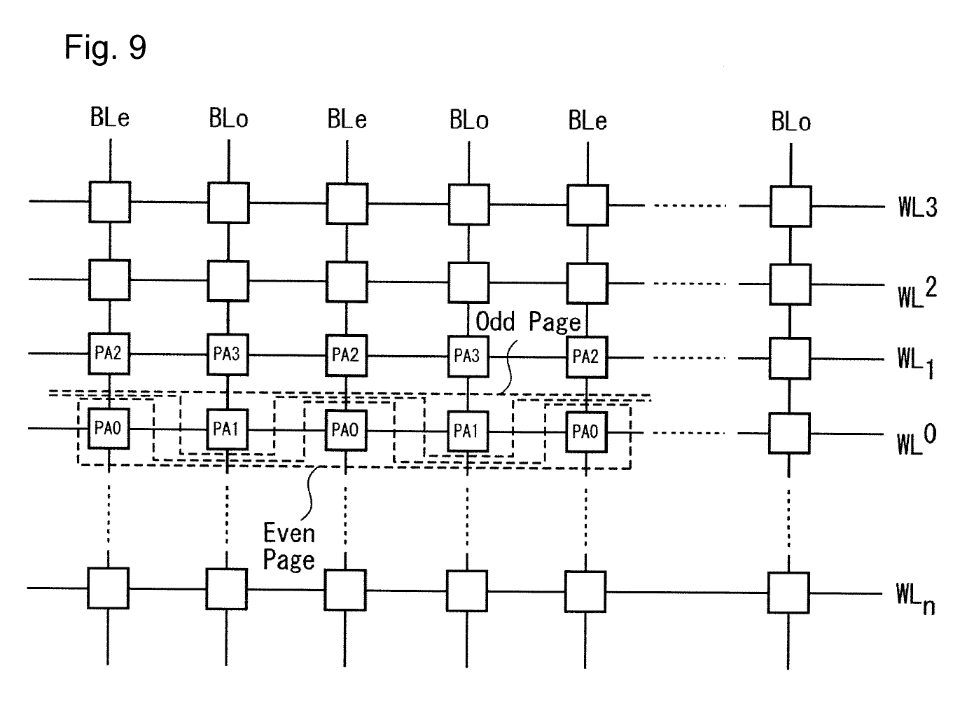

FIG. 9 shows a page address assignment of memory cells when the binary control circuit 111 is selected (binary programming mode). A page address PA 0 is assigned to the memory cell located at the intersection of the even number bit line BLe and the word line WL0. A page address PA 1 is assigned to the memory cell located at the intersection of the odd number bit line BLo and the word line WL0. A page address PA 2 is assigned to the memory cell located at the intersection of the even number bit line BLe and the word line WL1. A page address PA 3 is assigned to the memory cell located at the intersection of the odd number bit line BLo and the word line WL1. Thus, the binary control circuit 111 assigns one page address to one memory cell, and makes one memory cell memorize 1-bit of data.

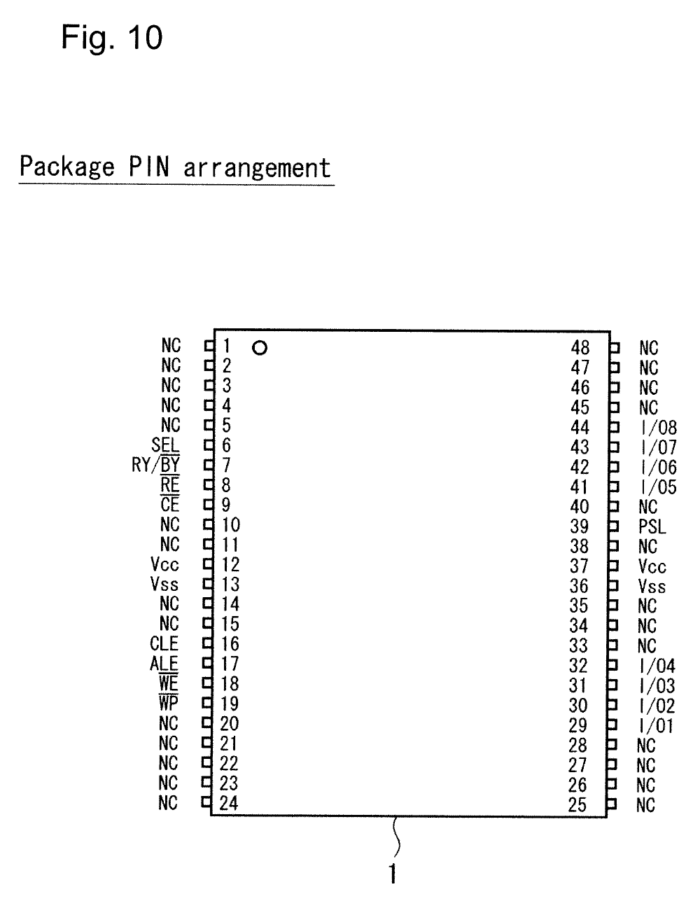

FIG. 10 shows a package pin assignment of the NAND type flash memory 1 according to the present embodiment. I/O signals are input or output through input/output terminals I/O1-I/O8. Thus, 8-bits of data (i.e., 1 Byte of data) may be input or output through the input/output terminals I/O1-I/O8. The I/O signals are configured to be address, data (write data and read data), and a command signals, based on the control signals described below. The above mentioned page address is input/output as an address signal. The NAND type flash memory 1 also has control signal terminals for a chip enable signal /CE, a write enable signal /WE, a read enable signal /RE, a command latch enable signal CLE, an address latch enable signal ALE, and a selection signal SEL.

The command latch enable (CLE) signal is a signal for latching the command into the NAND type flash memory 1. The data on the input/output terminals I/O1-I/O8 is taken in the NAND type flash memory 1 as command data when the CLE signals is “H” level at the time of rising or falling of the /WE signal.

The address latch enable (ALE) signal is a signal for latching the address data into the NAND type flash memory 1. The data on the input/output terminals I/O1-I/O8 is taken in the NAND type flash memory 1 as the address data when the ALE signal is “H” level at the time of rising or falling of the /WE signal.

The chip enable (/CE) signal is an activation signal of the NAND type flash memory 1. If the /CE signal is “H” level in the state of “Ready”, the NAND type flash memory 1 enters a standby mode which is a lower power consumption mode. The write enable (/WE) signal is a signal for latching the data into the NAND type flash memory 1 from the input/output terminals I/O1-I/O8. The read enable (/RE) signal is a signal to output the read data through the input/output terminals I/O1-I/O8.

The selection (SEL) signal is a signal for selecting the multi-value control circuit 110 or the binary control circuit 111. For example, the multi-value control circuit 110 is selected when “H” level signal is supplied to the terminal of the selection signal SEL, and the binary control circuit 111 is selected when “L” level signal is supplied to the terminal of the selection signal SEL. By this selection signal SEL, the multi-value control circuit 110 or the binary control circuit 111 may alternatively be activated. For example, “H” level signal or “L” level signal may be connected to the input terminal of the selection signal SEL at the time of mounting the NAND type flash memory 1 on the printed circuit board. On the other hand, the selection signal SEL may be driven by a logic gate or a switch so that the selection may be made dynamically.

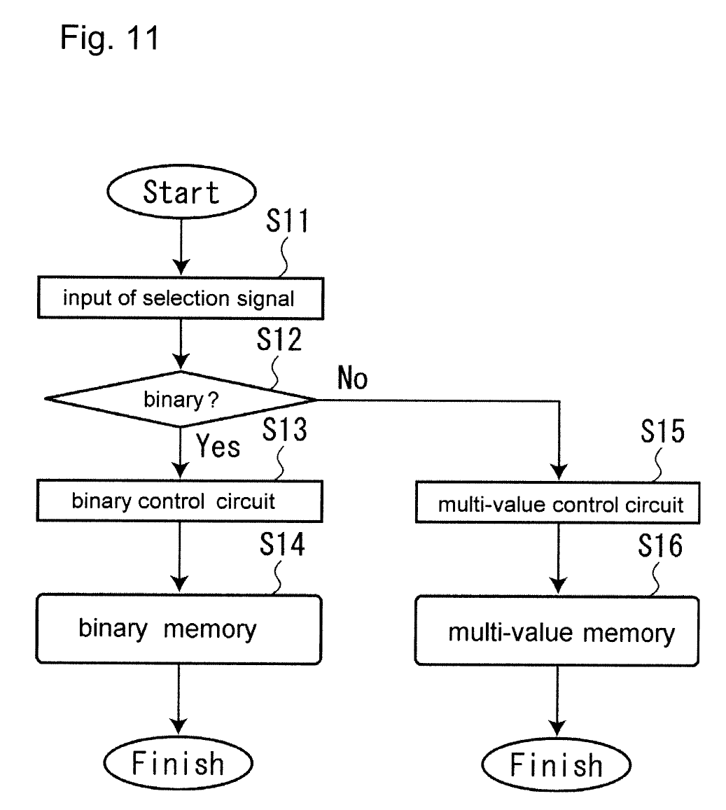

FIG. 11 is a flow chart showing the operation of the NAND type flash memory 1 according to the present embodiment.

First, the selection signal SEL, which is the control signal for selecting the programming mode, is input to the terminal of the selection signal SEL (Step S11). For example, when selecting the multi-value control circuit 110, “H” level signal is supplied to the terminal of the selection signal SEL. When selecting the binary control circuit 111, “L” level signal is supplied to the terminal of the selection signal SEL.

Next, the NAND type flash memory 1 detects which of the programming modes was selected by the selection signal SEL between the binary and four-value modes (Step S12). When the programming mode is binary, the binary control circuit 111 is activated (Step S13), the multi-value control circuit 110 is deactivated, and the NAND type flash memory 1 operates as a binary memory in programming data into the memory cell array so that 1-bit of data may be programmed into each memory cell (Step S14).

On the other hand, when the programming mode is not binary (when the programming mode is the four-value mode) in the step S12, the multi-value control circuit 110 is activated (Step S15), the binary control circuit 111 is deactivated, and the NAND type flash memory 1 operates as the multi-value memory in programming data into the memory cell array so that 2-bits of data may be programmed into each memory cell (Step S16).

As explained above, the nonvolatile semiconductor memory according to the present embodiment can change the programming mode between binary and four-value modes by inputting a selection (SEL) signal. The binary memory is suitable for the high-speed access, and the multi-value memory is suitable for mass data storing. For this reason, the user can select an appropriate binary or multi-value memory characteristic according to the usage of the nonvolatile semiconductor memory.

Moreover, in order to improve the programming characteristics of the nonvolatile semiconductor memory, using a multiple-value memory configured to be accessed as a binary memory can be considered. However, in such a case, the controller which controls the nonvolatile semiconductor memory must perform a complicated access to the nonvolatile semiconductor memory. For example, in the page address assignment as shown in FIG. 6, the controller would have to access the nonvolatile semiconductor memory with inconsecutive page addresses P0, P2, P4, and P6, if the memory was to be accessed as a binary memory. In order to carry out such an access, the controller needs to recognize the page address assignment of the nonvolatile semiconductor memory.

On the other hand, in the nonvolatile semiconductor memory according to the present embodiment, when the programming mode is binary, the binary control circuit 111 assigns one page address to one memory cell, and makes one memory cell memorize 1-bit data. Therefore, the controller can access the nonvolatile semiconductor memory with consecutive page addresses without requiring the controller to be configured to detect the page address assignment of the nonvolatile semiconductor memory.

### The Second Embodiment

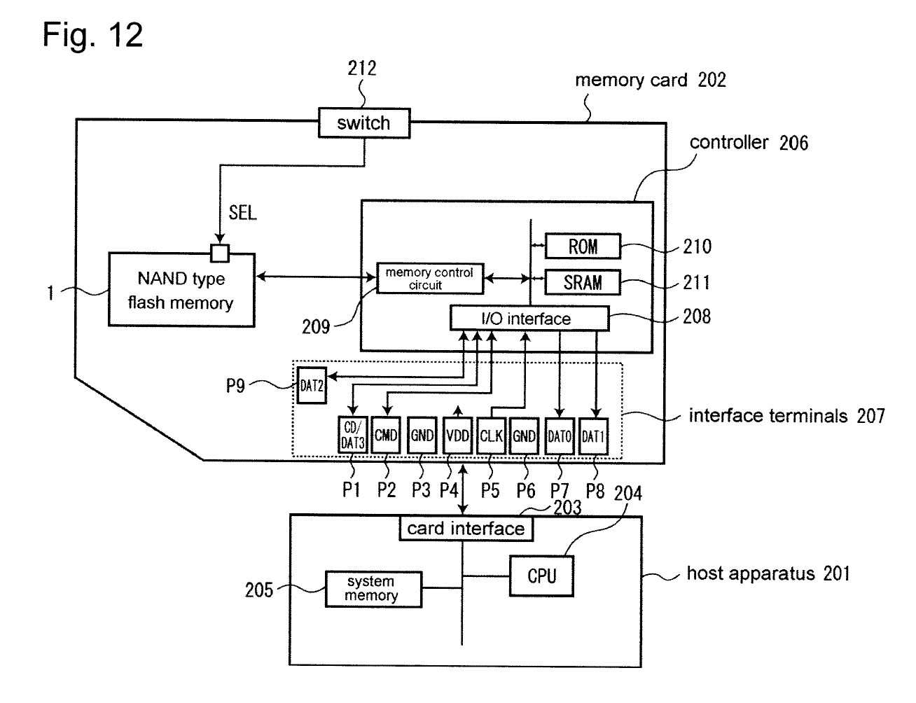

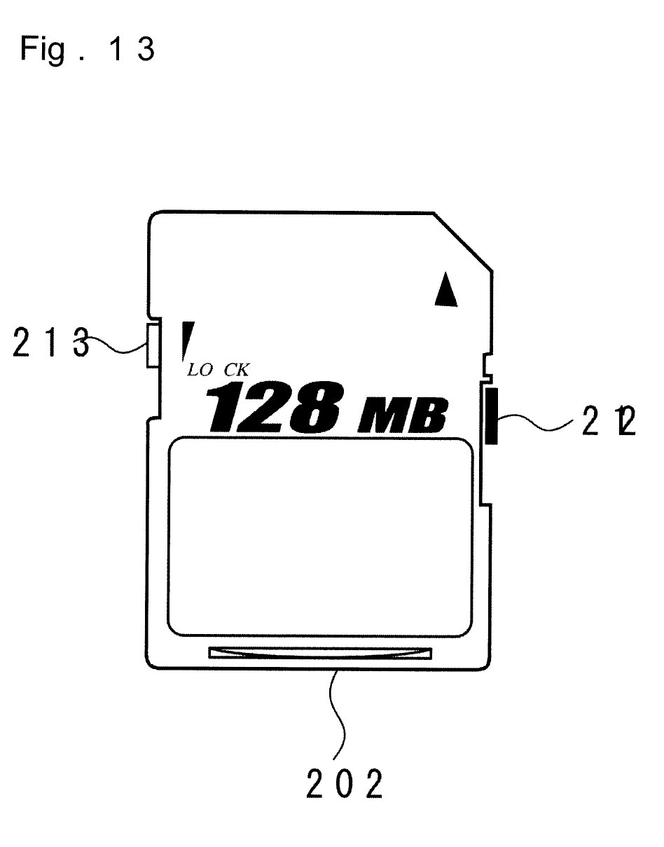

FIGS. 12 and 13 show an embodiment of a memory card 202. In this example, the memory card 202 is an SD™ card (hereinafter, a memory card).

FIG. 12 is a drawing showing an outline composition of the memory card according to the present embodiment. A host apparatus 201 includes a card interface 203 with which two or more memory cards 202 can be simultaneously connected, and a system memory 205 such as RAM (Random access memory), and a CPU 204 which control an entire operation of the host apparatus 201. An example of the host apparatus 201 is a personal computer.

The memory card 202 is inserted into or detached from the card interface 203 of the host apparatus 201. The memory card 202 operates using power supplied from the host apparatus 201, and performs processing according to a request from the host apparatus 201. The memory card 202 has the NAND type flash memory 1, the controller 206, and a mechanical switch 212 for selecting the programming mode of the NAND type flash memory 1. The NAND type flash memory 1 was explained in the first embodiment. In this embodiment, the NAND type flash memory 1 and the controller 206 are implemented using LSI (Large Scale Integrated circuit) chips formed respectively on different semiconductor chips. These LSI chips may be sealed with a resin. The two or more LSI chips may be collectively sealed into a single package, or the LSI chips may be separately sealed into different packages. Otherwise, the LSI chips may be mounted in the memory card 202 without the resin seal.

The controller 206 manages the physical condition of the NAND type flash memory 1. The controller 109 has an I/O interface 208, a memory control circuit 209, ROM (Read Only Memory) 210, SRAM (Static Random Access Memory) 211. The I/O interface 208 is connected with interface terminals 207 and functions as an interface between the memory card 202 and the host apparatus 201. The memory control circuit 209 communicates with the NAND type flash memory 1 in response to a request of the host apparatus 201.

The memory control circuit 209 generates various kinds of table information to be stored in the SRAM 211 by performing predetermined processing based on a firmware (a control program) stored in the ROM 210 when the memory card 202 receives power from the host apparatus 201. Moreover, the memory control circuit 209 receives a write command, a read command, and an erase command from the host apparatus 201. The memory control circuit 209 performs predetermined processing to the NAND type flash memory 1 and controls the transfer of data thorough the SRAM 211 to the NAND type flash memory 1.

The ROM 210 is a memory which stores the control program used by the memory control circuit 209. The SRAM 211 is a memory used as a work memory of the memory control circuit 209. The SRAM 211 temporarily stores the control program and the table information.

The interface terminals 207 are electrically connected with the connector pins of the host apparatus 201 when the memory card 202 is inserted in a card slot of the host apparatus 201. Data signals (DAT0-DAT3) are assigned to pins P1, P7, P8, and P9. The pin P1 is assigned to a card detected signal (CD). A pin P2 is assigned to a command (CMD) and a pin 5 is assigned to a clock (CLK). Grounding potential (Vss) is supplied to pins P3 and P6, and power supply potential (Vdd) is supplied to a pin P4.

In such a composition, the memory card 202 performs communication between the host apparatus 201 through the interface terminals 207. For example, when data is written in the NAND type flash memory 1, the controller 206 receives the write command supplied to the pin P2 as a serial signal, in response to the clock signal supplied to the pin P5.

The mechanical switch 212 is a slide-type switch. By sliding the mechanical switch 212, the programming mode of the NAND type flash memory 1 can be switched between binary and four-value modes. For example, the mechanical switch 212 can select “H” level signal or “L” level signal to be input to the terminal of the selection (SEL) signal of the NAND type flash memory 1. As explained in the first embodiment, when “H” level signal is supplied to the terminal of the selection (SEL) signal, the NAND type flash memory 1 operates as the multi-value memory, and when “L” level signal is supplied to the terminal of the selection (SEL) signal, the NAND type flash memory 1 operates as the binary memory.

FIG. 13 shows a package of the memory card 202. A mechanical switch 213 is a switch for a write protection. By sliding the mechanical switch 213, an unintentional overwrite of data to the NAND type flash memory 1 can be prevented. The mechanical switch 212 for selecting the programming mode is provided on the opposite side of a card case to the mechanical switch 213. The mechanical switch 212 may be provided together with the mechanical switch 213 for the write protection.

The memory card according to the present embodiment can switch the programming mode of the memory cells between the binary and four-value modes by the mechanical switch 212.

Although the second embodiment showed the case where the programming mode of the NAND type flash memory 1 is changed with the mechanical switch 212, the other methods may be adopted to switch the programming mode. For example, the host apparatus 201 may send a command for switching the programming mode to the memory card 202.

Moreover, although the programming mode of the NAND type flash memory 1 is changed by supplying the predetermined potential to the terminal of the selection (SEL) signal in the first and second embodiments, the present invention is not limited to this case. The programming mode may be changed by other means. For example, the programming mode may be changed by sending a command to the NAND type flash memory 1.

Furthermore, the memory card is a SD™ card in the first and second embodiments. However, the present invention is not limited to the SD™ card. For example, the present invention can be applied to other memory systems such as a USB (Universal Serial Bus) memory.

Furthermore, the nonvolatile semiconductor memory is the NAND type flash memory in the first and second embodiments. However, the present invention is not limited to the NAND type flash memory, but can be applied to other nonvolatile semiconductor memories.

Furthermore, although the programming mode is changed between the binary and four-value modes in the first and second embodiments, other combinations of the programming modes may be adopted. For example, the programming mode may be changed between the four-value mode (2 bits of data per memory cell) and an eight-value mode (3 bits of data per memory cell), or between the eight-value mode (3 bits of data per memory cell) and a sixteen-value mode (4 bits of data per memory cell). That is, the present invention can be applied when changing between the mode to program M bits (M is two or more integers) of data into one memory cell, and the mode to program N bits (N is a integer less than M) of data into one memory cell. Furthermore, although the programming method is changed between two modes in the first and second embodiment, the programming method may be changed among three or more modes.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A nonvolatile semiconductor memory comprising:
a plurality of memory cells each configured to store M bits of data, M being an integer greater than 1;
a selection circuit configured to select a first mode or a second mode according to an instruction from outside of the nonvolatile semiconductor memory; and
a program circuit configured to program M bits of data into each of the memory cells when the selection circuit selects the first mode and program N bits of data into each of the memory cells when the selection circuit selects the second mode, N being an integer less than M.

2. The nonvolatile semiconductor memory according to claim 1, further comprising a selection pin configured to receive a voltage as the instruction from the outside of the nonvolatile semiconductor memory, the selection circuit further configured to select the first mode or the second mode according to the voltage received by the selection pin.

3. The nonvolatile semiconductor memory according to claim 1, further comprising an address buffer configured to receive a page address designating a page to be programmed,
each of the memory cells is assigned with N different page addresses when the selection circuit selects the first mode, and
each of the memory cells is assigned with M different page addresses when the selection circuit selects the second mode.

4. The nonvolatile semiconductor memory according to claim 1, wherein the M is 2 and the N is 1.

5. The nonvolatile semiconductor memory according to claim 1, wherein the nonvolatile semiconductor memory is a NAND type flash memory.

6. A memory system configured to transfer data to and from a host apparatus, the system comprising:
a plurality of interface terminals configured to electrically connect to the host apparatus;
a plurality of memory cells each configured to store M bits of data, M being an integer greater than 1;
a selection circuit configured to select a first mode or a second mode according to an instruction from outside of the memory system; and
a program circuit configured to program M bits of data into each of the memory cells when the selection circuit selects the first mode and program N bits of data into each of the memory cells when the selection circuit selects the second mode, N being an integer less than M.

7. The memory system according to claim 6, further comprising an address buffer configured to receive a page address designating a page to be programmed,
each of the memory cells is assigned with N different page addresses when the selection circuit selects the first mode, and
each of the memory cells is assigned with M different page addresses when the selection circuit selects the second mode.

8. The memory system according to claim 6, wherein the M is 2 and the N is 1.

9. The memory system according to claim 6, wherein the memory system includes a memory card configured to be attached to the host apparatus and detached from the host apparatus.

10. A memory system configured to transfer data to and from a host apparatus, the memory system comprising:
a nonvolatile semiconductor memory;
a mechanical switch configured to be switched to one of plural states by a user of the memory system; and
a controller configured to access the nonvolatile semiconductor memory in response to a request from the host apparatus, the nonvolatile semiconductor memory comprising:
a plurality of memory cells each configured to store M bits of data, M being an integer greater than 1;
a selection circuit configured to select a first mode or a second mode according to the state of the mechanical switch; and
a program circuit configured to program M bits of data into each of the memory cells when the selection circuit selects the first mode and program N bits of data into each of the memory cells when the selection circuit selects the second mode, N being an integer less than M.

11. The memory system according to claim 10, the nonvolatile semiconductor memory further comprising a selection pin configured to receive a voltage from outside of the nonvolatile semiconductor memory, the selection circuit further configured to select the first mode or the second mode according to the voltage received by the selection pin, and
the voltage received by the selection pin is determined by the state of the mechanical switch.

12. The memory system according to claim 10, the nonvolatile semiconductor memory further comprising an address buffer configured to receive a page address designating a page to be programmed,
each of the memory cells is assigned with N different page addresses when the selection circuit selects the first mode, and
each of the memory cell is assigned with M different page addresses when the selection circuit selects the second mode.

13. The memory system according to claim 10, wherein the M is 2 and the N is 1.

14. The memory system according to claim 10, wherein the nonvolatile semiconductor memory is a NAND type flash memory.

15. The memory system according to claim 10, wherein the memory system includes a memory card configured to be attached to the host apparatus and detached from the host apparatus.
